(19) United States
(12) Patent Application Publication
(10) Pub. No.: US 2026/0254428 A1
(43) Pub. Date: Aug. 27, 2026

(54) AMPLIFIER WITH INCREASED GAIN STABILITY

(71) Applicant: QUALCOMM Incorporated, San Diego, CA (US)

(72) Inventors: Pingli HUANG, Cupertino, CA (US); Lalitkumar NATHAWAD, Pleasanton, CA (US)

(21) Appl. No.: 19/065,025

(22) Filed: Feb. 27, 2025

(30) Foreign Application Priority Data
Feb. 21, 2025 (GR) 20250100140

(51) Int. Cl. H03G 3/30

(52) U.S. Cl. CPC H03G 3/3036; H03G 2201/103; H03G 2201/307

(57) ABSTRACT

Certain aspects of the present disclosure are directed towards an amplifier. The amplifier generally includes: a first input transistor with a source coupled to a first node; a second input transistor with a source coupled to a second node; at least one resistive element coupled between the first node and the second node; a first current mirror including a first set of transistors with gates coupled to a drain of the first input transistor, a drain of a transistor of the first set of transistors being coupled to the first node; and a second current mirror including a second set of transistors with gates coupled to a drain of the second input transistor, a drain of a transistor of the second set of transistors being coupled to the second node.

### CROSS-REFERENCE TO RELATED APPLICATION(S)

This application claims priority to Greece application No. 20250100140, filed Feb. 21, 2025, which is hereby incorporated by reference herein.

### TECHNICAL FIELD

Certain aspects of the present disclosure generally relate to electronic circuits and, more particularly, to an amplifier.

### BACKGROUND

Wireless communication devices are widely deployed to provide various communication services such as telephony, video, data, messaging, broadcasts, and so on. Such wireless communication devices may transmit and/or receive radio frequency (RF) signals via any of various suitable radio access technologies (RATs) including, but not limited to, Fifth Generation (5G) New Radio (NR), Long Term Evolution (LTE), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., WiFi), and the like.

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more amplifiers for signal amplification.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description,” one will understand how the features of this disclosure provide advantages that include amplifier gain stability as well as reduced power and area consumption.

Certain aspects of the present disclosure are directed towards an amplifier. The amplifier generally includes: a first input transistor with a source coupled to a first node; a second input transistor with a source coupled to a second node; at least one resistive element coupled between the first node and the second node; a first current mirror including a first set of transistors with gates coupled to a drain of the first input transistor, a drain of a transistor of the first set of transistors being coupled to the first node; and a second current mirror including a second set of transistors with gates coupled to a drain of the second input transistor, a drain of a transistor of the second set of transistors being coupled to the second node.

Certain aspects of the present disclosure are directed towards a method for signal amplification by an amplifier. The method generally includes: receiving a first input signal at a gate of a first input transistor with a source coupled to a first node; receiving a second input signal at a gate of a second input transistor with a source coupled to a second node, the first input signal and the second input signal forming a differential signal pair; generating a first current from the first node to the second node based on the first input signal and the second input signal, wherein at least one resistive element is coupled between the first node and the second node; generating, via a transistor of a first set of transistors of a first current mirror coupled to the first input transistor, a second current to be provided to the first node based on the first input signal; and generating, via a transistor of a second set of transistors of a second current mirror coupled to the second input transistor, a third current to be provided to the second node based on the second input signal.

Certain aspects of the present disclosure are directed towards an electronic device. The electronic device generally includes an analog-to-digital converter (ADC) and a residue amplifier configured to amplify a residue analog signal from the ADC. In some aspects, the residue amplifier includes: a first input transistor with a source coupled to a first node; a second input transistor with a source coupled to a second node; at least one resistive element coupled between the first node and the second node; a first current mirror including a first set of transistors with gates coupled to a drain of the first input transistor, a drain of a transistor of the first set of transistors being coupled to the first node; and a second current mirror including a second set of transistors with gates coupled to a drain of the second input transistor, a drain of a transistor of the second set of transistors being coupled to the second node.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram conceptually illustrating a design of an example base station (BS) and user equipment (UE), in which aspects of the present disclosure may be practiced.

FIG. 3 is a block diagram of an example radio frequency (RF) transceiver, in which aspects of the present disclosure may be practiced.

FIG. 4 is a circuit diagram of an example amplifier, in accordance with certain aspects of the present disclosure.

FIG. 5 is a flow diagram illustrating example operations for signal amplification, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards an amplifier providing increased gain stability across process, voltage, and temperature (PVT) variations. The amplifier may be used as a residue amplifier for an analog-to-digital converter (ADC), although certain aspects of the present disclosure may be applied for any suitable application. Typical residue amplifiers may be implemented with calibration circuitry to calibrate the gain of the amplifier. With the increased stability of the amplifier described herein, such calibration circuitry may not be used (or at least simplified), reducing device area and power consumption.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

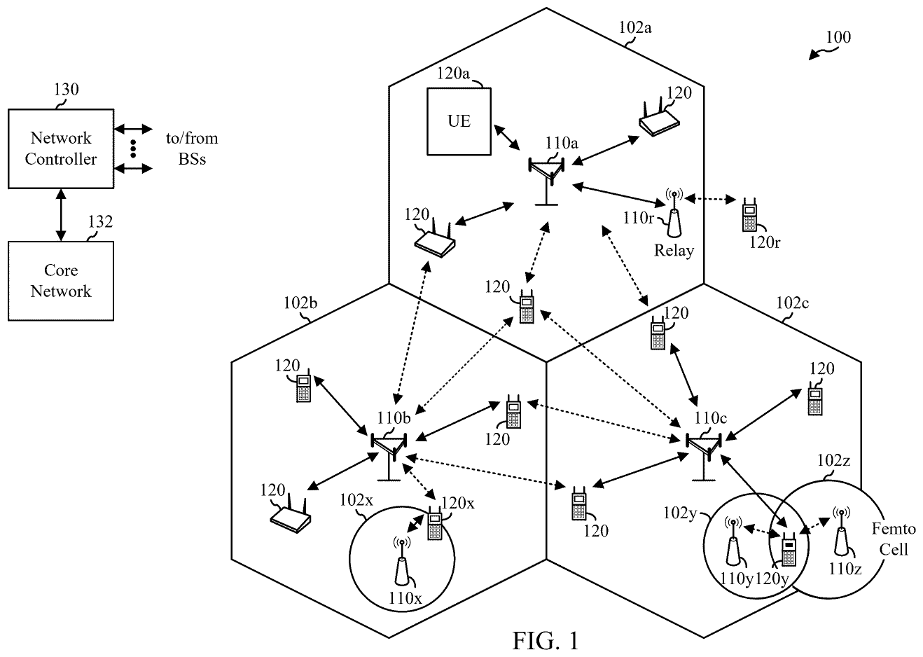

FIG. 1 illustrates an example wireless communications network 100, in which aspects of the present disclosure may be practiced. For example, the wireless communications network 100 may be a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation/Third Generation (2G/3G) network), or a code division multiple access (CDMA) system (e.g., a 2G/3G network), or may be configured for communications according to an IEEE standard such as one or more of the 802.11 standards, etc.

As illustrated in FIG. 1, the wireless communications network 100 may include a number of base stations (BSs) 110a-z (each also individually referred to herein as “BS 110” or collectively as “BSs 110”) and other network entities. A BS may also be referred to as an access point (AP), an evolved Node B (eNodeB or eNB), a next generation Node B (gNodeB or gNB), or some other terminology.

A BS 110 may provide communication coverage for a particular geographic area, sometimes referred to as a “cell,” which may be stationary or may move according to the location of a mobile BS. In some examples, the BSs 110 may be interconnected to one another and/or to one or more other BSs or network nodes (not shown) in wireless communications network 100 through various types of backhaul interfaces (e.g., a direct physical connection, a wireless connection, a virtual network, or the like) using any suitable transport network. In the example shown in FIG. 1, the BSs 110a, 110b, and 110c may be macro BSs for the macro cells 102a, 102b, and 102c, respectively. The BS 110x may be a pico BS for a pico cell 102x. The BSs 110y and 110z may be femto BSs for the femto cells 102y and 102z, respectively. A BS may support one or multiple cells.

The BSs 110 communicate with one or more user equipments (UEs) 120a-y (each also individually referred to herein as “UE 120” or collectively as “UEs 120”) in the wireless communications network 100. A UE may be fixed or mobile and may also be referred to as a user terminal (UT), a mobile station (MS), an access terminal, a station (STA), a client, a wireless device, a mobile device, or some other terminology. A user terminal may be a wireless device, such as a cellular phone, a smartphone, a personal digital assistant (PDA), a handheld device, a wearable device, a wireless modem, a laptop computer, a tablet, a personal computer, etc.

The BSs 110 are considered transmitting entities for the downlink and receiving entities for the uplink. The UEs 120 are considered transmitting entities for the uplink and receiving entities for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink. Nᵤₚ UEs may be selected for simultaneous transmission on the uplink, N_{dn} UEs may be selected for simultaneous transmission on the downlink. Nᵤₚ may or may not be equal to N_{dn}, and Nᵤₚ and N_{dn} may be static values or can change for each scheduling interval. Beam-steering or some other spatial processing technique may be used at the BSs 110 and/or UEs 120.

The UEs 120 (e.g., 120x, 120y, etc.) may be dispersed throughout the wireless communications network 100, and each UE 120 may be stationary or mobile. The wireless communications network 100 may also include relay stations (e.g., relay station 110r), also referred to as relays or the like, that receive a transmission of data and/or other information from an upstream station (e.g., a BS 110a or a UE 120r) and send a transmission of the data and/or other information to a downstream station (e.g., a UE 120 or a BS 110), or that relays transmissions between UEs 120, to facilitate communication between devices.

The BSs 110 may communicate with one or more UEs 120 at any given moment on the downlink and uplink. The downlink (i.e., forward link) is the communication link from the BSs 110 to the UEs 120, and the uplink (i.e., reverse link) is the communication link from the UEs 120 to the BSs 110. A UE 120 may also communicate peer-to-peer with another UE 120.

The wireless communications network 100 may use multiple transmit and multiple receive antennas for data transmission on the downlink and uplink. BSs 110 may be equipped with a number Nap of antennas to achieve transmit diversity for downlink transmissions and/or receive diversity for uplink transmissions. A set Nu of UEs 120 may receive downlink transmissions and transmit uplink transmissions. Each UE 120 may transmit user-specific data to and/or receive user-specific data from the BSs 110. In general, each UE 120 may be equipped with one or multiple antennas. The Nu UEs 120 can have the same or different numbers of antennas.

The wireless communications network 100 may be a time division duplex (TDD) system or a frequency division duplex (FDD) system. For a TDD system, the downlink and uplink share the same frequency band. For an FDD system, the downlink and uplink use different frequency bands. The wireless communications network 100 may also utilize a single carrier or multiple carriers for transmission. Each UE 120 may be equipped with a single antenna (e.g., to keep costs down) or multiple antennas (e.g., where the additional cost can be supported).

A network controller 130 (also sometimes referred to as a “system controller”) may be in communication with a set of BSs 110 and provide coordination and control for these BSs 110 (e.g., via a backhaul). In certain cases (e.g., in a 5G NR system), the network controller 130 may include a centralized unit (CU) and/or a distributed unit (DU). In certain aspects, the network controller 130 may be in communication with a core network 132 (e.g., a 5G Core Network (5GC)), which provides various network functions such as Access and Mobility Management, Session Management, User Plane Function, Policy Control Function, Authentication Server Function, Unified Data Management, Application Function, Network Exposure Function, Network Repository Function, Network Slice Selection Function, etc.

In certain aspects of the present disclosure, the BSs 110 and/or the UEs 120 may include an amplifier implemented with increased gain stability across PVT variations, as described in more detail herein.

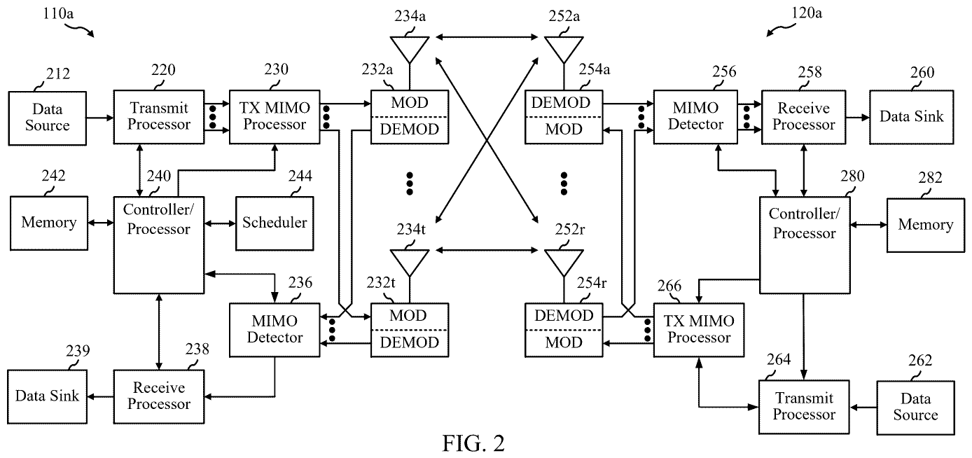

FIG. 2 illustrates example components of BS 110a and UE 120a (e.g., from the wireless communications network 100 of FIG. 1), in which aspects of the present disclosure may be implemented.

On the downlink, at the BS 110a, a transmit processor 220 may receive data from a data source 212, control information from a controller/processor 240, and/or possibly other data (e.g., from a scheduler 244). The various types of data may be sent on different transport channels. For example, the control information may be designated for the physical broadcast channel (PBCH), physical control format indicator channel (PCFICH), physical hybrid automatic repeat request (HARQ) indicator channel (PHICH), physical downlink control channel (PDCCH), group common PDCCH (GC PDCCH), etc. The data may be designated for the physical downlink shared channel (PDSCH), etc. A medium access control (MAC)-control element (MAC-CE) is a MAC layer communication structure that may be used for control command exchange between wireless nodes. The MAC-CE may be carried in a shared channel such as a PDSCH, a physical uplink shared channel (PUSCH), or a physical sidelink shared channel (PSSCH).

The processor 220 may process (e.g., encode and symbol map) the data and control information to obtain data symbols and control symbols, respectively. The transmit processor 220 may also generate reference symbols, such as for the primary synchronization signal (PSS), secondary synchronization signal (SSS), PBCH demodulation reference signal (DMRS), and channel state information reference signal (CSI-RS).

A transmit (TX) multiple-input, multiple-output (MIMO) processor 230 may perform spatial processing (e.g., precoding) on the data symbols, the control symbols, and/or the reference symbols, if applicable, and may provide output symbol streams to the modulators (MODs) in transceivers 232a-232t. Each modulator in transceivers 232a-232t may process a respective output symbol stream (e.g., for orthogonal frequency division multiplexing (OFDM), etc.) to obtain an output sample stream. Each of the transceivers 232a-232t may further process (e.g., convert to analog, amplify, filter, and upconvert) the output sample stream to obtain a downlink signal. Downlink signals from the transceivers 232a-232t may be transmitted via the antennas 234a-234t, respectively.

At the UE 120a, the antennas 252a-252r may receive the downlink signals from the BS 110a and may provide received signals to the transceivers 254a-254r, respectively. The transceivers 254a-254r may condition (e.g., filter, amplify, downconvert, and digitize) a respective received signal to obtain input samples. Each demodulator (DEMOD) in the transceivers 232a-232t may further process the input samples (e.g., for OFDM, etc.) to obtain received symbols. A MIMO detector 256 may obtain received symbols from all the demodulators in transceivers 254a-254r, perform MIMO detection on the received symbols if applicable, and provide detected symbols. A receive processor 258 may process (e.g., demodulate, deinterleave, and decode) the detected symbols, provide decoded data for the UE 120a to a data sink 260, and provide decoded control information to a controller/processor 280.

On the uplink, at UE 120a, a transmit processor 264 may receive and process data (e.g., for the physical uplink shared channel (PUSCH)) from a data source 262 and control information (e.g., for the physical uplink control channel (PUCCH)) from the controller/processor 280. The transmit processor 264 may also generate reference symbols for a reference signal (e.g., the sounding reference signal (SRS)). The symbols from the transmit processor 264 may be precoded by a TX MIMO processor 266 if applicable, further processed by the modulators (MODs) in transceivers 254a-254r (e.g., for single-carrier frequency division multiplexing (SC-FDM), etc.), and transmitted to the BS 110a. At the BS 110a, the uplink signals from the UE 120a may be received by the antennas 234, processed by the demodulators in transceivers 232a-232t, detected by a MIMO detector 236 if applicable, and further processed by a receive processor 238 to obtain decoded data and control information sent by the UE 120a. The receive processor 238 may provide the decoded data to a data sink 239 and the decoded control information to the controller/processor 240.

The memories 242 and 282 may store data and program codes for BS 110a and UE 120a, respectively. The memories 242 and 282 may also interface with the controllers/processors 240 and 280, respectively. A scheduler 244 may schedule UEs for data transmission on the downlink and/or uplink.

In certain aspects of the present disclosure, the transceivers 232 and/or the transceivers 254 may include an amplifier implemented with increased gain stability across PVT variations, as described in more detail herein.

NR may utilize orthogonal frequency division multiplexing (OFDM) with a cyclic prefix (CP) on the uplink and downlink. NR may support half-duplex operation using time division duplexing (TDD). OFDM and single-carrier frequency division multiplexing (SC-FDM) partition the system bandwidth into multiple orthogonal subcarriers, which are also commonly referred to as tones, bins, etc. Each subcarrier may be modulated with data. Modulation symbols may be sent in the frequency domain with OFDM and in the time domain with SC-FDM. The spacing between adjacent subcarriers may be fixed, and the total number of subcarriers may be dependent on the system bandwidth. The system bandwidth may also be partitioned into subbands. For example, a subband may cover multiple resource blocks (RBs).

### Example RF Transceiver

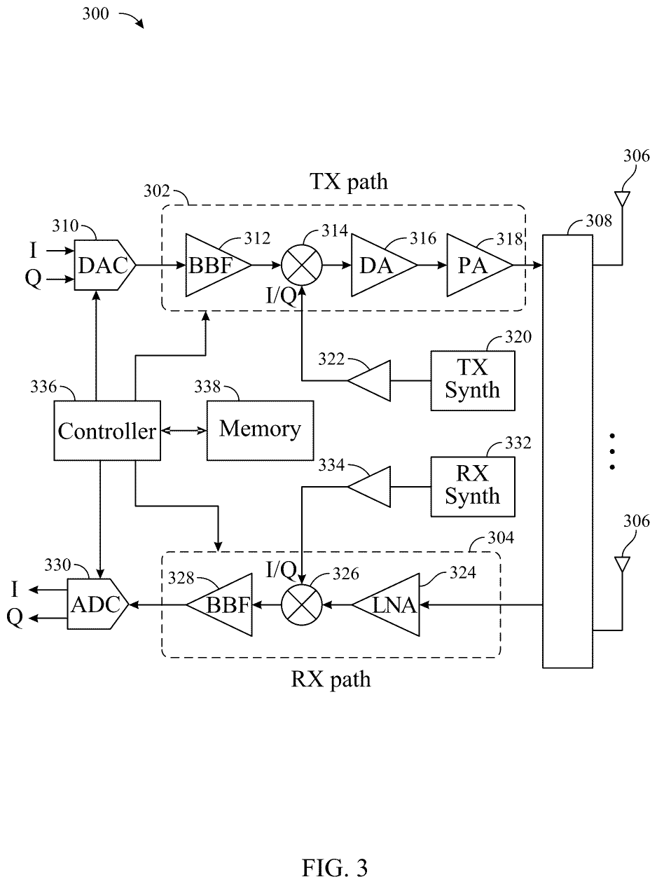

FIG. 3 is a block diagram of an example radio frequency (RF) transceiver circuit 300, in accordance with certain aspects of the present disclosure. The RF transceiver circuit 300 includes at least one transmit (TX) path 302 (also known as a “transmit chain”) for transmitting signals via one or more antennas 306 and at least one receive (RX) path 304 (also known as a “receive chain”) for receiving signals via the antennas 306. When the TX path 302 and the RX path 304 share an antenna 306, the paths may be connected with the antenna via an interface 308, which may include any of various suitable RF devices, such as a switch, a duplexer, a diplexer, a multiplexer, and the like.

Receiving in-phase (I) and/or quadrature (Q) baseband analog signals from a digital-to-analog converter (DAC) 310, the TX path 302 may include a baseband filter (BBF) 312, a mixer 314, a driver amplifier (DA) 316, and a power amplifier (PA) 318. The BBF 312, the mixer 314, the DA 316, and the PA 318 may be included in a radio frequency integrated circuit (RFIC). For certain aspects, the PA 318 may be external to the RFIC.

The BBF 312 filters the baseband signals received from the DAC 310, and the mixer 314 mixes the filtered baseband signals with a transmit local oscillator (LO) signal to convert the baseband signal of interest to a different frequency (e.g., upconvert from baseband to a radio frequency). This frequency-conversion process produces the sum and difference frequencies between the LO frequency and the frequencies of the baseband signal of interest. The sum and difference frequencies are referred to as the “beat frequencies.” The beat frequencies are typically in the RF range, such that the signals output by the mixer 314 are typically RF signals, which may be amplified by the DA 316 and/or by the PA 318 before transmission by the antenna(s) 306. While one mixer 314 is illustrated, several mixers may be used to upconvert the filtered baseband signals to one or more intermediate frequencies and to thereafter upconvert the intermediate frequency (IF) signals to a frequency for transmission.

The RX path 304 may include a low noise amplifier (LNA) 324, a mixer 326, and a baseband filter (BBF) 328. The LNA 324, the mixer 326, and the BBF 328 may be included in one or more RFICs, which may or may not be the same RFIC that includes the TX path components. RF signals received via the antenna(s) 306 may be amplified by the LNA 324, and the mixer 326 mixes the amplified RF signals with a receive local oscillator (LO) signal to convert the RF signal of interest to a different baseband frequency (e.g., downconvert). The baseband signals output by the mixer 326 may be filtered by the BBF 328 before being converted by an analog-to-digital converter (ADC) 330 to digital I and/or Q signals for digital signal processing. In some aspects, the ADC 330 may be implemented with a residue amplifier (e.g., in a pipelined ADC). Certain aspects provide an amplifier with increased stability across PVT variations. The amplifier may be used to implement the residue amplifier for the ADC 330.

Certain transceivers may employ frequency synthesizers with a variable-frequency oscillator (e.g., a voltage-controlled oscillator (VCO) or a digitally controlled oscillator (DCO)) to generate a stable, tunable LO with a particular tuning range. Thus, the transmit LO may be produced by a TX frequency synthesizer 320, which may be buffered or amplified by amplifier 322 before being mixed with the baseband signals in the mixer 314. Similarly, the receive LO may be produced by an RX frequency synthesizer 332, which may be buffered or amplified by amplifier 334 before being mixed with the RF signals in the mixer 326. For certain aspects, a single frequency synthesizer may be used for both the TX path 302 and the RX path 304. In certain aspects, the TX frequency synthesizer 320 and/or RX frequency synthesizer 332 may include a frequency multiplier, such as a frequency doubler, that is driven by an oscillator (e.g., a VCO) in the frequency synthesizer.

A controller 336 (e.g., controller/processor 280 in FIG. 2) may direct the operation of the RF transceiver circuit 300A, such as transmitting signals via the TX path 302 and/or receiving signals via the RX path 304. The controller 336 may be a processor, a digital signal processor (DSP), an application-specific integrated circuit (ASIC), a field-programmable gate array (FPGA) or other programmable logic device (PLD), discrete gate or transistor logic, discrete hardware components, or any combination thereof. A memory 338 (e.g., memory 282 in FIG. 2) may store data and/or program codes for operating the RF transceiver circuit 300. The controller 336 and/or the memory 338 may include control logic (e.g., complementary metal-oxide-semiconductor (CMOS) logic).

While FIGS. 1-3 provide wireless communications as an example application in which certain aspects of the present disclosure may be implemented to facilitate understanding, certain aspects described herein may be used for any of various other suitable systems.

### Example Amplifier with Increased Gain Stability

Open-loop amplifiers could, for example, be used as residue amplifiers in a pipelined analog-to-digital converter (ADC), where a pipelined ADC could be used to implement the ADC 330 of FIG. 3. A residue amplifier generally refers to an amplifier that receives a residue analog signal (e.g., a remaining analog signal after analog-to-digital conversion) and amplifies the residue analog signal for further processing to increase the resolution of the ADC.

Certain aspects are directed towards an amplifier with reduced gain variation over process, voltage, and temperature (PVT) variations as compared to some conventional implementations. A typical residue amplifier may experience gain variations over PVT. Thus, some pipeline successive approximation register (SAR) ADCs may use calibration circuitry for the residue amplifier to reduce the gain variations. With the reduced gain variation of the amplifier described herein, the pipeline SAR calibration circuitry that would otherwise be used for gain calibration may not be used or at least simplified, saving area and power consumption. While the amplifier described herein may be used as a residue amplifier for an ADC, the amplifier can be used for any suitable application to provide increased gain stability.

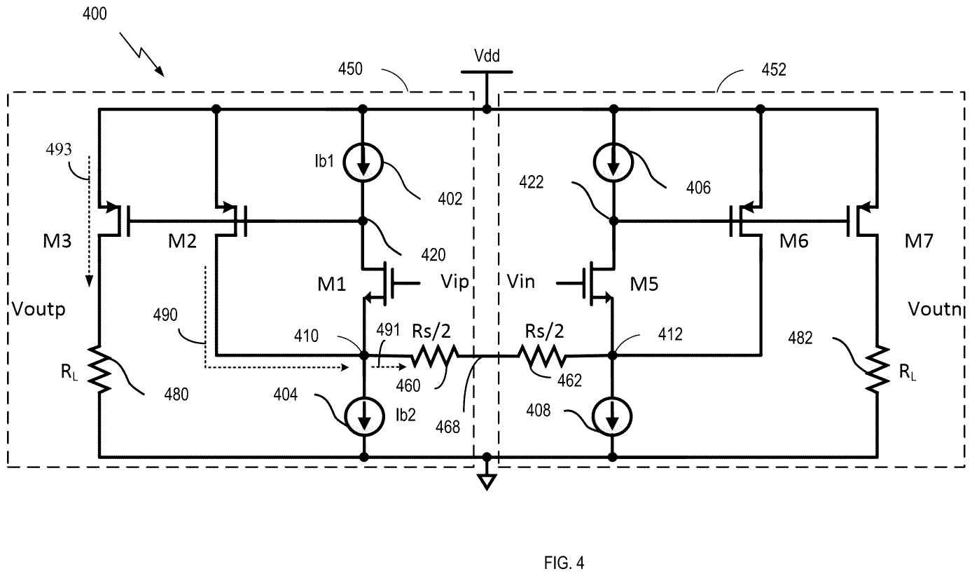

FIG. 4 is a circuit diagram of an example amplifier 400, in accordance with certain aspects of the present disclosure. The amplifier 400 is a differential amplifier receiving a positive input voltage (Vip) and negative input voltage (Vin). The amplifier 400 includes a circuit portion 450 for generating a positive output voltage (Voutp) and a circuit portion 452 for generating a negative output voltage (Voutn). The amplifier 400 includes input transistors M1, M5 with gates receiving Vip and Vin, respectively.

With respect to circuit portion 450, the amplifier 400 also includes a current source 402 coupled between a voltage rail Vdd and a drain of the input transistor M1. The source of the input transistor M1 is coupled to node 410. A current source 404 is coupled between the node 410 and a reference potential node (e.g., electric ground). The current source 402 may source a current Ib1 to node 410 through transistor M1, and the current source 404 may sink a current Ib2 from node 410. The amplifier 400 may also include a transistor M2 with a source coupled to Vdd, a drain coupled to node 410, and a gate coupled to node 420, which is coupled to the drain of transistor M1. The amplifier 400 also includes a transistor M3 with a source coupled to Vdd and a gate coupled to a gate of transistor M2. The transistors M2 and M3 form a current mirror. As shown, a drain of the transistor M3 is coupled to a load resistive element 480 which may have a resistance R_{L}. The input transistor M1 may be an n-type metal-oxide-semiconductor (NMOS) transistor, and transistors M2, M3 may be p-type metal-oxide-semiconductor (PMOS) transistors.

The circuit portion 452 may be implemented with a similar structure as circuit portion 450. For example, with respect to circuit portion 452, the amplifier 400 may include a current source 406 coupled between a voltage rail Vdd and a drain of the input transistor M5. The source of the input transistor M5 is coupled to node 412. A current source 408 is coupled between the node 412 and the reference potential node (e.g., electric ground). The amplifier 400 may also include a transistor M6 with a source coupled to Vdd, a drain coupled to node 412, and a gate coupled to node 422, which is coupled to the drain of transistor M5. The amplifier 400 also includes a transistor M7 with a source coupled to Vdd and a gate coupled to a gate of transistor M6. The transistors M6 and M7 form a current mirror. As shown, a drain of the transistor M7 is coupled to a load resistive element 482 which may have a resistance R_{L}. The input transistor M5 may be an NMOS transistor, and transistors M6, M7 may be PMOS transistors.

In some aspects, one or more resistive elements may be coupled between nodes 410, 412. For example, a resistive element having a resistance R_{S} may be coupled between nodes 410, 412. The resistive element may be represented by resistive elements 460, 462 each having a resistance of R_{S}/2.

The input transistors M1, M5 form respective source followers. For example, the node 410 (e.g., at source of transistor M1) may track Vip at the gate of transistor M1. Assume a differential input signal is applied as an input to amplifier 400. Thus, Vip may increase by a specific voltage, and Vin may decrease by the specific voltage. Due to transistor M1 forming a source follower, the voltage at node 410 may increase by the specific voltage, and the voltage at node 412 may decrease the specific voltage, resulting in current 491 flowing from node 410 to node 412 to increase. The current Ib1 sourced by current source 402 to node 410 and the current Ib2 sunk by current source 404 from node 410 are effectively fixed (e.g., due to current sources 402, 404 being fixed current sources). Thus, the increase in the current 491 from node 410 to node 412 caused by the applied differential input signal may be supplied via transistor M2. That is, the source-to-drain current 490 of transistor M2 increases in response to the applied differential input signal and flows to node 410, supplying the increase in the current 491.

In some aspects, the current Ib2 may be greater than the current Ib1 to set proper bias voltage and current levels. For example, the current Ib2 may be set to be greater than the current Ib1, effectively setting a bias level with regards to current 490 flowing across transistor M2.

As described, in response to the differential input signal being applied, the voltage at node 410 may increase by a specific voltage, and the voltage at node 412 may decrease by the same voltage. Thus, the voltage at node 468 between resistive elements 460, 462 (e.g., both having a resistance of R_{S}/2) may remain unchanged. As a result, the node 468 may effectively be considered a virtual ground for the amplifier 400.

When Vip increases due to the differential input signal being applied, the voltage at node 420 coupled to the gate of transistor M2 may decrease. As shown, the source of transistor M2 is coupled Vdd. Thus, the decrease of the voltage at node 420 (e.g., at gate of transistor M2) results in an increase of the source to gate voltage of transistor M2. The increase in the source to gate voltage of transistor M2 results in the source to drain current (e.g., current 490) of transistor M2 increasing to supply the increase in the current 491.

As described, the transistors M2, M3 form a current mirror. Thus, the current 490 may be mirrored by transistor M3 to supply an output current 493 to the load resistive element 480, generating Voutp.

In some cases, transistors M2, M3 may have the same size, and the output current 493 supplied to resistive element 480 may mirror the current 490. In some aspects, the size of transistor M3 may be more than the size of transistor M2 by a certain factor. In this case, the output current supplied to resistive element 480 may be greater than the current 490 by the same factor. The circuit portion 452 operates in a similar fashion as circuit portion 450 to generate Voutn. The gain of the amplifier 400 may be represented by the equation:

$$Gain = \frac{{R}_{L}}{{R}_{s} / 2} \times \frac{{W}_{M 3}}{{W}_{M 2}}$$

where W_{M3} is the width of transistor M3 and W_{M2} is the width of transistor M2. The size (e.g., width) of transistor M3 may be equal to the size transistor M7, and the size (e.g., width) of transistor M2 may be equal to the size of transistor M6. As shown, the gain of the amplifier 400 is dependent on resistances R_{L} and R_{S} and the sizes of transistors M2, M3, which may be set with precision and may be stable across PVT variations. As a result, the amplifier 400 provides increased gain stability over PVT variations as compared to conventional implementations. By reducing gain variations, gain calibration circuitry may be simplified (or not used) which may also reduce the overall power consumption and area of the amplifier.

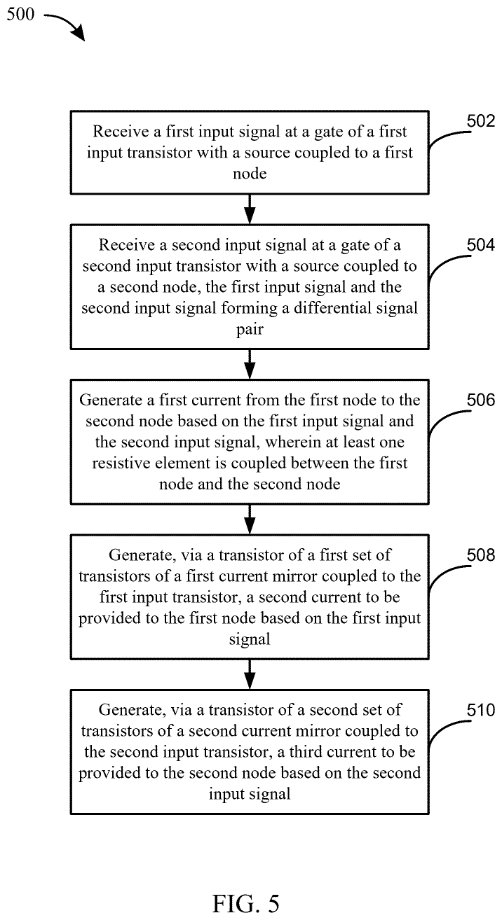

FIG. 5 is a flow diagram illustrating example operations 500 for signal amplification, in accordance with certain aspects of the present disclosure. The operations 500 may be performed by an amplifier such as the amplifier 400 of FIG. 4.

At block 502, the amplifier may receive a first input signal (e.g., Vip) at a gate of a first input transistor (e.g., transistor M1) with a source coupled to a first node (e.g., node 410). At block 504, the amplifier may receive a second input signal (e.g., Vin) at a gate of a second input transistor (e.g., transistor M5) with a source coupled to a second node (e.g., node 412), the first input signal and the second input signal forming a differential signal pair.

At block 506, the amplifier may generate a first current (e.g., current 491) from the first node to the second node based on the first input signal and the second input signal. At least one resistive element (e.g., resistive elements 460, 462) may be coupled between the first node and the second node.

At block 508, the amplifier may generate, via a transistor of a first set of transistors (e.g., transistors M2, M3) of a first current mirror coupled to the first input transistor, a second current (e.g., current 490) to be provided to the first node based on the first input signal. At block 510, the amplifier may generate, via a transistor of a second set of transistors (e.g., transistors M6, M7) of a second current mirror coupled to the second input transistor, a third current to be provided to the second node based on the second input signal.

In some aspects, gates of the first set of transistors are coupled to a drain of the first input transistor, the amplifier providing the second current via a drain of the transistor of the first set of transistors being coupled to the first node. Gates of the second set of transistors may be coupled to a drain of the second input transistor, the amplifier providing the third current via a drain of the transistor of the second set of transistors being coupled to the second node.

In some aspects, the amplifier may provide a first output current (e.g., current 493) to a first load resistive element (e.g., resistive element 480) via another transistor of the first set of transistors. The amplifier may provide a second output current to a second load resistive element via another transistor of the second set of transistors. A gain of the amplifier may be set based on a resistance of each of the at least one resistive element, the first load resistive element, and the second load resistive element.

In some aspects, the amplifier may provide, via a first current source (e.g., current source 402), a fourth current (e.g., Ib1) from a voltage rail (e.g., Vdd) to a drain of the first input transistor. In some aspects, an amplifier may sink, via a second current source (e.g., current source 404), a fifth current (e.g., current Ib2) from the first node to a reference potential node.

In some aspects, the amplifier may provide, via a third current source (e.g., current source 406), a sixth current from the voltage rail to a drain of the second input transistor. The amplifier may also sink, via a fourth current source (e.g., current source 408), a seventh current from the second node to the reference potential node. In some aspects, the first current source, the second current source, the third current source, and the fourth current source are constant current sources. In some aspects, the fifth current may be less than the first current, and the seventh current may be less than the sixth current. In some aspects, in response to the first input signal and the second input signal, the first current from the first node to the second node may increase by a specific amount, the second current may increase by the specific amount, and the third current may decrease by the specific amount.

In some aspects, the first input transistor may form a first source follower circuit. The second input transistor may form a second source follower circuit.

### Example Aspects

In addition to the various aspects described above, specific combinations of aspects are within the scope of the present disclosure, some of which are detailed below:

Aspect 1: An amplifier, comprising: a first input transistor with a source coupled to a first node; a second input transistor with a source coupled to a second node; at least one resistive element coupled between the first node and the second node; a first current mirror including a first set of transistors with gates coupled to a drain of the first input transistor, a drain of a transistor of the first set of transistors being coupled to the first node; and a second current mirror including a second set of transistors with gates coupled to a drain of the second input transistor, a drain of a transistor of the second set of transistors being coupled to the second node.

Aspect 2: The amplifier of Aspect 1, wherein: a drain of another transistor of the first set of transistors is coupled to a first load resistive element; and a drain of another transistor of the second set of transistors is coupled to a second load resistive element.

Aspect 3: The amplifier of Aspect 2, wherein a gain of the amplifier is set based on a resistance of each of the at least one resistive element, the first load resistive element, and the second load resistive element.

Aspect 4: The amplifier according to any of Aspects 1-3, further comprising: a first current source coupled between a voltage rail and the drain of the first input transistor; a second current source coupled between the first node and a reference potential node; a third current source coupled between the voltage rail and the drain of the second input transistor; and a fourth current source coupled between the second node and the reference potential node.

Aspect 5: The amplifier of Aspect 4, wherein the first current source, the second current source, the third current source, and the fourth current source are constant current sources.

Aspect 6: The amplifier of Aspect 4 or 5, wherein: the second current source is configured to sink a first amount of current from the first node; and the first current source is configured to source a second amount of current to the drain of the first input transistor, the second amount of current being less than the first amount of current.

Aspect 7: The amplifier according to any of Aspects 1-6, wherein sources of the first set of transistors and the second set of transistors are coupled to a voltage rail.

Aspect 8: The amplifier according to any of Aspects 1-7, wherein, in response to a differential input signal provided to the amplifier: a current across the at least one resistive element from the first node to the second node is configured to increase by a specific amount; and a source to the drain current of the transistor of the first set of transistors is configured to increase by the specific amount.

Aspect 9: The amplifier according to any of Aspects 1-8, wherein: the first input transistor forms a first source follower circuit; and the second input transistor forms a second source follower circuit.

Aspect 10: A method for signal amplification by an amplifier, comprising: receiving a first input signal at a gate of a first input transistor with a source coupled to a first node; receiving a second input signal at a gate of a second input transistor with a source coupled to a second node, the first input signal and the second input signal forming a differential signal pair; generating a first current from the first node to the second node based on the first input signal and the second input signal, wherein at least one resistive element is coupled between the first node and the second node; generating, via a transistor of a first set of transistors of a first current mirror coupled to the first input transistor, a second current to be provided to the first node based on the first input signal; and generating, via a transistor of a second set of transistors of a second current mirror coupled to the second input transistor, a third current to be provided to the second node based on the second input signal.

Aspect 11: The method of Aspect 10, wherein: gates of the first set of transistors are coupled to a drain of the first input transistor, the method further comprising providing the second current via a drain of the transistor of the first set of transistors coupled to the first node; and gates of the second set of transistors are coupled to a drain of the second input transistor, the method further comprising providing the third current via a drain of the transistor of the second set of transistors coupled to the second node.

Aspect 12: The method of Aspect 10 or 11, further comprising: providing a first output current to a first load resistive element via another transistor of the first set of transistors; and providing a second output current to a second load resistive element via another transistor of the second set of transistors.

Aspect 13: The method of Aspect 12, wherein a gain of the amplifier is set based on a resistance of each of the at least one resistive element, the first load resistive element, and the second load resistive element.

Aspect 14: The method according to any of Aspects 10-13, further comprising: providing, via a first current source, a fourth current from a voltage rail to a drain of the first input transistor; sinking, via a second current source, a fifth current from the first node to a reference potential node; providing, via a third current source, a sixth current from the voltage rail to a drain of the second input transistor; and sinking, via a fourth current source, a seventh current from the second node to the reference potential node.

Aspect 15: The method of Aspect 14, wherein the first current source, the second current source, the third current source, and the fourth current source are constant current sources.

Aspect 16: The method of Aspect 14 or 15, wherein: the fifth current is less than the first current; and the seventh current is less than the sixth current.

Aspect 17: The method according to any of Aspects 10-16, wherein, in response to the first input signal and the second input signal: the first current from the first node to the second node increases by a specific amount; the second current increases by the specific amount; and the third current decreases by the specific amount.

Aspect 18: An electronic device, comprising: an analog-to-digital converter (ADC); and a residue amplifier configured to amplify a residue analog signal from the ADC, the residue amplifier including: a first input transistor with a source coupled to a first node; a second input transistor with a source coupled to a second node; at least one resistive element coupled between the first node and the second node; a first current mirror including a first set of transistors with gates coupled to a drain of the first input transistor, a drain of a transistor of the first set of transistors being coupled to the first node; and a second current mirror including a second set of transistors with gates coupled to a drain of the second input transistor, a drain of a transistor of the second set of transistors being coupled to the second node.

Aspect 19: The electronic device of Aspect 18, wherein: a drain of another transistor of the first set of transistors is coupled to a first load resistive element; and a drain of another transistor of the second set of transistors is coupled to a second load resistive element.

Aspect 20: The electronic device of Aspect 19, wherein a gain of the residue amplifier is set based on a resistance of each of the at least one resistive element, the first load resistive element, and the second load resistive element.

### Additional Considerations

The above description provides examples, and is not limiting of the scope, applicability, or examples set forth in the claims. Changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method which is practiced using other structure, functionality, or structure and functionality in addition to, or other than, the various aspects of the disclosure set forth herein. It should be understood that any aspect of the disclosure disclosed herein may be embodied by one or more elements of a claim.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes, and variations may be made in the arrangement, operation, and details of the methods and apparatus described above without departing from the scope of the claims.

1. An amplifier, comprising:
a first input transistor with a source coupled to a first node;
a second input transistor with a source coupled to a second node;
at least one resistive element coupled between the first node and the second node;
a first current mirror including a first set of transistors with gates coupled to a drain of the first input transistor, a drain of a transistor of the first set of transistors being coupled to the first node; and
a second current mirror including a second set of transistors with gates coupled to a drain of the second input transistor, a drain of a transistor of the second set of transistors being coupled to the second node.

2. The amplifier of claim 1, wherein:
a drain of another transistor of the first set of transistors is coupled to a first load resistive element; and
a drain of another transistor of the second set of transistors is coupled to a second load resistive element.

3. The amplifier of claim 2, wherein a gain of the amplifier is set based on a resistance of each of the at least one resistive element, the first load resistive element, and the second load resistive element.

4. The amplifier of claim 1, further comprising:
a first current source coupled between a voltage rail and the drain of the first input transistor;
a second current source coupled between the first node and a reference potential node;
a third current source coupled between the voltage rail and the drain of the second input transistor; and
a fourth current source coupled between the second node and the reference potential node.

5. The amplifier of claim 4, wherein the first current source, the second current source, the third current source, and the fourth current source are constant current sources.

6. The amplifier of claim 4, wherein:
the first current source is configured to source a first amount of current to the drain of the first input transistor; and
the second current source is configured to sink a second amount of current from the first node, the first amount of current being less than the second amount of current.

7. The amplifier of claim 1, wherein sources of the first set of transistors and the second set of transistors are coupled to a voltage rail.

8. The amplifier of claim 1, wherein, in response to a differential input signal provided to the amplifier:
a current across the at least one resistive element from the first node to the second node is configured to increase by a specific amount; and
a source to the drain current of the transistor of the first set of transistors is configured to increase by the specific amount.

9. The amplifier of claim 1, wherein:
the first input transistor forms a first source follower circuit; and
the second input transistor forms a second source follower circuit.

10. A method for signal amplification by an amplifier, comprising:
receiving a first input signal at a gate of a first input transistor with a source coupled to a first node;
receiving a second input signal at a gate of a second input transistor with a source coupled to a second node, the first input signal and the second input signal forming a differential signal pair;
generating a first current from the first node to the second node based on the first input signal and the second input signal, wherein at least one resistive element is coupled between the first node and the second node;
generating, via a transistor of a first set of transistors of a first current mirror coupled to the first input transistor, a second current to be provided to the first node based on the first input signal; and
generating, via a transistor of a second set of transistors of a second current mirror coupled to the second input transistor, a third current to be provided to the second node based on the second input signal.

11. The method of claim 10, wherein:
gates of the first set of transistors are coupled to a drain of the first input transistor, the method further comprising providing the second current via a drain of the transistor of the first set of transistors coupled to the first node; and
gates of the second set of transistors are coupled to a drain of the second input transistor, the method further comprising providing the third current via a drain of the transistor of the second set of transistors coupled to the second node.

12. The method of claim 10, further comprising:
providing a first output current to a first load resistive element via another transistor of the first set of transistors; and
providing a second output current to a second load resistive element via another transistor of the second set of transistors.

13. The method of claim 12, wherein a gain of the amplifier is set based on a resistance of each of the at least one resistive element, the first load resistive element, and the second load resistive element.

14. The method of claim 10, further comprising:
providing, via a first current source, a fourth current from a voltage rail to a drain of the first input transistor;
sinking, via a second current source, a fifth current from the first node to a reference potential node;
providing, via a third current source, a sixth current from the voltage rail to a drain of the second input transistor; and
sinking, via a fourth current source, a seventh current from the second node to the reference potential node.

15. The method of claim 14, wherein the first current source, the second current source, the third current source, and the fourth current source are constant current sources.

16. The method of claim 14, wherein:
the fourth current is less than the fifth current; and
the sixth current is less than the seventh current.

17. The method of claim 10, wherein, in response to the first input signal and the second input signal:
the first current from the first node to the second node increases by a specific amount;
the second current increases by the specific amount; and
the third current decreases by the specific amount.

18. An electronic device, comprising:
an analog-to-digital converter (ADC); and
a residue amplifier configured to amplify a residue analog signal from the ADC, the residue amplifier including:
a first input transistor with a source coupled to a first node;
a second input transistor with a source coupled to a second node;
at least one resistive element coupled between the first node and the second node;
a first current mirror including a first set of transistors with gates coupled to a drain of the first input transistor, a drain of a transistor of the first set of transistors being coupled to the first node; and
a second current mirror including a second set of transistors with gates coupled to a drain of the second input transistor, a drain of a transistor of the second set of transistors being coupled to the second node.

19. The electronic device of claim 18, wherein:
a drain of another transistor of the first set of transistors is coupled to a first load resistive element; and
a drain of another transistor of the second set of transistors is coupled to a second load resistive element.

20. The electronic device of claim 19, wherein a gain of the residue amplifier is set based on a resistance of each of the at least one resistive element, the first load resistive element, and the second load resistive element.
